(19) United States
(12) Patent Application Publication
(10) Pub. No.: US 2024/0033859 A1
(43) Pub. Date: Feb. 1, 2024

(54) LASER MACHINING METHOD

(71) Applicant: HAMAMATSU PHOTONICS K.K., Hamamatsu-shi, Shizuoka (JP)

(72) Inventors: Yo SUGIMOTO, Hamamatsu-shi, Shizuoka (JP); Takeshi SAKAMOTO, Hamamatsu-shi, Shizuoka (JP); Takafumi OGIWARA, Hamamatsu-shi, Shizuoka (JP); Naoki UCHIYAMA, Hamamatsu-shi, Shizuoka (JP); Takashi KURITA, Hamamatsu-shi, Shizuoka (JP); Ryo YOSHIMURA, Hamamatsu-shi, Shizuoka (JP)

(73) Assignee: HAMAMATSU PHOTONICS K.K., Hamamatsu-shi, Shizuoka (JP)

(21) Appl. No.: 18/268,383

(22) PCT Filed: Dec. 20, 2021
(86) PCT No.: PCT/JP2021/047071

§ 371 Date: Jun. 20, 2023

(30) Foreign Application Priority Data
Dec. 25, 2020 (JP) 2020-217217

(51) Int. Cl. B23K 26/38; B23K 37/00

(52) U.S. Cl. CPC B23K 26/38; B23K 37/00

(57) ABSTRACT

A laser processing method includes a first step of preparing a wafer including a plurality of functional elements disposed to be adjacent to each other via a street, a second step of, after the first step, forming a modified region in the wafer along a line passing through the street, and a third step of, after the second step, irradiating the street with laser light such that a surface layer of the street is removed, and a fracture extending from the modified region reaches a bottom surface of a recess formed by removing the surface layer, along the line.

### TECHNICAL FIELD

The present disclosure relates to a laser processing method.

### BACKGROUND ART

In a wafer including a plurality of functional elements disposed to be adjacent to each other via streets, an insulating film (Low-k film or the like) and a metal structure (metal piles, metal pads, and the like) may be formed on the surface layer of the street. In such a case, if a modified region is formed in the wafer along a line passing through the street, and the wafer is chipped for each functional element by extending a fracture from the modified region, the quality of the chip may be deteriorated, for example, film peeling may occur in the portion along the street. Therefore, when the wafer is chipped for each functional element, grooving processing of removing the surface layer of the street by irradiating the street with laser light may be performed (see Patent Literatures 1 and 2, for example).

### CITATION LIST

### Patent Literature

Patent Literature 1: Japanese Unexamined Patent Publication No. 2007-173475
Patent Literature 2: Japanese Unexamined Patent Publication No. 2017-011040

### SUMMARY OF INVENTION

### Technical Problem

In the techniques as described above, for example, it may be difficult to chip the wafer for each functional element, depending on the magnitude of the extension amount of the fracture from the modified region.

Therefore, an object of the present disclosure is to provide a laser processing method capable of reliably chipping a wafer for each functional element.

### Solution to Problem

According to an aspect of the present disclosure, a laser processing method includes a first step of preparing a wafer including a plurality of functional elements disposed to be adjacent to each other via a street, a second step of, after the first step, forming a modified region in the wafer along a line passing through the street, and a third step of, after the second step, irradiating the street with laser light such that a surface layer of the street is removed, and a fracture extending from the modified region reaches a bottom surface of a recess formed by removing the surface layer, along the line.

In this laser processing method, after the modified region is formed in the wafer along the line in the second step, laser processing (also referred to as “grooving processing” below) of removing the surface layer of the street is performed in the third step. In the grooving processing, the fracture extending from the modified region in the wafer formed in the second step reaches the bottom surface of the recess formed by removing the surface layer of the street, along the line. Therefore, it is possible to reliably chip the wafer for each functional element by the fracture reaching the bottom surface of the recess.

The laser processing method according to the aspect of the present disclosure may further include a grinding step of grinding and thinning the wafer. In this case, it is possible to obtain a wafer having a desired thickness.

In the laser processing method according to the aspect of the present disclosure, the grinding step may be performed after the first step and before the second step. For example, when the prepared wafer is thicker than a predetermined thickness, there is a possibility that it is difficult to form the modified region in the wafer. In this regard, by performing the grinding step before the second step, it is possible to form the modified region in the thinned wafer even when the prepared wafer is thicker than the predetermined thickness. Thus, it is possible to suppress the difficulty in forming the modified region in the wafer.

In the laser processing method according to the aspect of the present disclosure, the grinding step may be performed after the second step and before the third step. For example, when the wafer in which the modified region is formed is transported, if the thickness of the wafer is thin, there is a possibility that an unintended crack is likely to occur in the wafer. In this regard, by performing the grinding step after the second step, it is possible to suppress the occurrence of an unintended crack in the wafer.

In the laser processing method according to the aspect of the present disclosure, the grinding step may be performed after the third step. For example, when the wafer in which the modified region is formed therein and the surface layer of the street is removed is transported, if the thickness of the wafer is thin, there is a possibility that an unintended crack is likely to occur in the wafer. In this regard, by performing the grinding step after the third step, it is possible to suppress the occurrence of an unintended crack in the wafer.

The laser processing method according to the aspect of the present disclosure may further include an information acquisition step of acquiring fracture extension information regarding extension of a fracture before the third step. In the third step, the street may be irradiated with laser light based on the fracture extension information such that the surface layer is removed and the fracture reaches the bottom surface of the recess along the line. In this case, it is possible to acquire the fracture extension information and to perform grooving processing by using the fracture extension information.

In the laser processing method according to the aspect of the present disclosure, in the information acquisition step, the fracture extension information may be acquired based on an image capturing result obtained by an internal observation camera capturing an image of the wafer after the modified region is formed in the second step. In this case, it is possible to acquire the fracture extension information from the image capturing result of the internal observation camera.

In the laser processing method according to the aspect of the present disclosure, the fracture extension information may include information regarding whether or not the fracture has reached the street. In this case, it is possible to perform grooving processing by using, as the fracture extension information, information regarding whether or not the fracture has reached the street.

In the laser processing method according to the aspect of the present disclosure, in the third step, only a region not reached by the fracture along the line in the street may be irradiated with the laser light along the line based on the fracture extension information such that the surface layer is removed, and the fracture reaches the bottom surface of the recess along the line. In this case, grooving processing is performed only in the region not reached by the fracture along the line in the street. Thus, it is possible to efficiently perform grooving processing.

The laser processing method according to the aspect of the present disclosure may further include a protective film applying step of applying a protective film onto at least the street in the wafer before the second step. In this case, since it is possible to make the reflectance of the street be constant by the protective film, it is possible to accurately acquire the fracture extension information.

In the laser processing method according to the aspect of the present disclosure, in the second step, the modified region may be formed in the wafer along the line such that the fracture does not reach the street. For example, when the wafer after the second step is transported, if the fracture reaches the street, there is a possibility that the wafer warps due to the fracture, and an unintended crack is likely to occur in the wafer. In this regard, by preventing the fracture from reaching the street in the second step, it is possible to suppress the occurrence of an unintended crack in the wafer.

According to another aspect of the present disclosure, a laser processing method includes a first step of preparing a wafer including a plurality of functional elements disposed to be adjacent to each other via a street, a second step of, after the first step, forming a modified region in the wafer along a line passing through the street, a third step of, after the second step, irradiating the street with laser light such that a surface layer of the street is removed, and a fourth step of processing the wafer after the third step. In the third step, the street is irradiated with the laser light such that a fracture extending from the modified region reaches a bottom surface of a recess formed by removing the surface layer, along the line after the fourth step.

In this laser processing method, after the fourth step, the fracture extending from the modified region in the wafer formed in the second step reaches the bottom surface of the recess formed by removing the surface layer of the street, along the line. Therefore, it is possible to reliably chip the wafer for each functional element by the fracture reaching the bottom surface of the recess.

In the laser processing method according to the aspect of the present disclosure, the fourth step may be a grinding step of grinding and thinning the wafer.

### Advantageous Effects of Invention

According to the present disclosure, it is possible to provide a laser processing method capable of reliably chipping a wafer for each functional element.

### BRIEF DESCRIPTION OF DRAWINGS

FIG. 1 is a configuration diagram illustrating a laser processing device that forms a modified region in a wafer.

FIG. 2 is a configuration diagram illustrating a laser processing device that performs grooving processing.

FIG. 3 is a plan view illustrating a wafer to be processed.

FIG. 4 is a cross-sectional view illustrating a portion of the wafer illustrated in FIG. 3.

FIG. 5 is a plan view illustrating a portion of a street illustrated in FIG. 3.

FIG. 6 is a flowchart illustrating a laser processing method according to a first embodiment.

FIG. 7(a) is a cross-sectional view of a wafer for explaining the laser processing method in the first embodiment. FIG. 7(b) is a cross-sectional view of the wafer illustrating a continuation of FIG. 7(a).

FIG. 8(a) is a cross-sectional view of the wafer illustrating a continuation of FIG. 7(b). FIG. 8(b) is a cross-sectional view of the wafer illustrating a continuation of FIG. 8(a).

FIG. 9(a) is a cross-sectional view of the wafer illustrating a continuation of FIG. 8(b). FIG. 9(b) is a cross-sectional view taken along line A-A of FIG. 9(a).

FIG. 10(a) is a cross-sectional view of the wafer illustrating a continuation of FIG. 9(a). FIG. 10(b) is a cross-sectional view taken along line B-B of FIG. 10(a).

FIG. 11 is a cross-sectional view of the wafer illustrating a continuation of FIG. 10(a).

FIG. 12 is a flowchart illustrating a laser processing method according to a second embodiment.

FIG. 13(a) is a cross-sectional view of a wafer for explaining the laser processing method in the second embodiment. FIG. 13(b) is a cross-sectional view of the wafer illustrating a continuation of FIG. 13(a).

FIG. 14(a) is a cross-sectional view of the wafer illustrating a continuation of FIG. 13(b). FIG. 14(b) is a cross-sectional view of the wafer illustrating a continuation of FIG. 14(a).

FIG. 15 is a flowchart illustrating a laser processing method according to a third embodiment.

FIG. 16(a) is a cross-sectional view of a wafer for explaining the laser processing method in the third embodiment. FIG. 16(b) is a cross-sectional view of the wafer illustrating a continuation of FIG. 16(a).

FIG. 17(a) is a cross-sectional view of the wafer illustrating a continuation of FIG. 16(b). FIG. 17(b) is a cross-sectional view of the wafer illustrating a continuation of FIG. 17(a).

FIG. 18 is a cross-sectional view of the wafer illustrating a continuation of FIG. 17(b).

FIG. 19 is a flowchart illustrating a laser processing method according to a fourth embodiment.

FIG. 20(a) is a cross-sectional view of a wafer for explaining the laser processing method in the fourth embodiment. FIG. 20(b) is a cross-sectional view of the wafer illustrating a continuation of FIG. 20(a).

FIG. 21 is a cross-sectional view of the wafer illustrating a continuation of FIG. 20(b).

FIG. 22(a) is a cross-sectional view corresponding to FIG. 9(b) for explaining a laser processing method according to a modification example. FIG. 22 (b) is a cross-sectional view corresponding to FIG. for explaining the laser processing method according to the modification example.

### DESCRIPTION OF EMBODIMENTS

Hereinafter, embodiments of the present disclosure will be described in detail with reference to the drawings. The same or corresponding parts in the respective drawings are denoted with the same reference signs, and repetitive descriptions will be omitted.

[Configuration of Laser Processing Device]

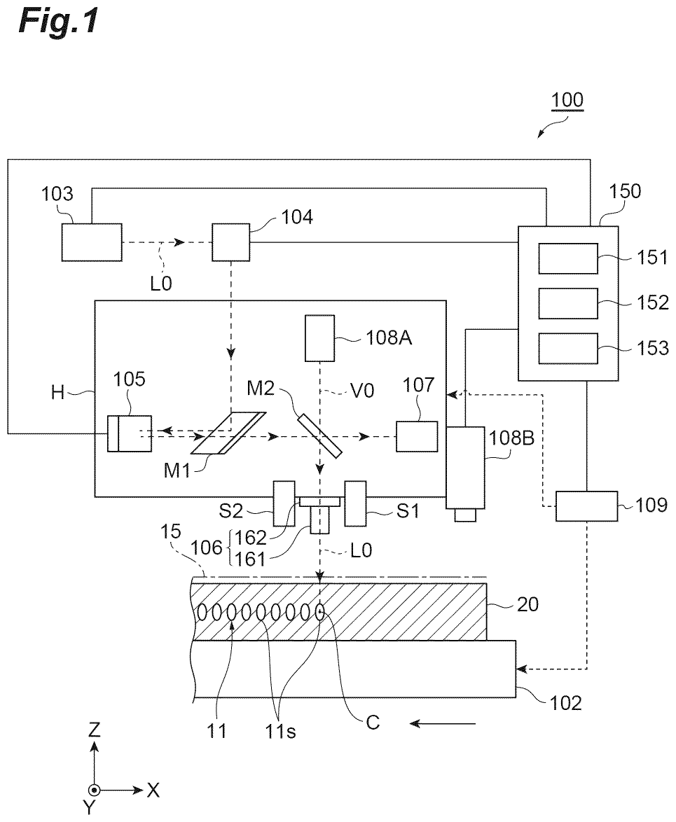

In a laser processing method in the embodiment, a modified region is formed in a wafer. As a device that forms the modified region in the wafer, for example, a laser processing device 100 illustrated in FIG. 1 can be used.

As illustrated in FIG. 1, the laser processing device 100 includes a support part 102, a light source 103, an optical axis adjusting part 104, a spatial light modulator 105, a converging part 106, an optical axis monitoring unit 107, a visible image capturing unit 108A, an infrared image capturing unit 108B, a movement mechanism 109, and a management unit 150. The laser processing device 100 forms a modified region 11 in a wafer 20 by irradiating the wafer 20 with laser light L0. In the following description, three directions perpendicular to each other are referred to as an X direction, a Y direction, and a Z direction, respectively. As an example, the X direction is a first horizontal direction, the Y direction is a second horizontal direction perpendicular to the first horizontal direction, and the Z direction is a vertical direction.

The support part 102 supports the wafer 20, for example, by attracting the wafer 20. The support part 102 is movable along each of the X direction and the Y direction. The support part 102 is rotatable about a rotation axis along the Z direction. The light source 103 emits the laser light L0 by, for example, a pulse oscillation method. The laser light L0 has transmittance with respect to the wafer 20. The optical axis adjusting part 104 adjusts the optical axis of the laser light L0 emitted from the light source 103. The optical axis adjusting part 104 is configured by, for example, a plurality of reflection mirrors of which positions and angles can be adjusted.

The spatial light modulator 105 is disposed in a laser processing head H. The spatial light modulator 105 modulates the laser light L0 output from the light source 103. The spatial light modulator 105 is a spatial light modulator (SLM) of a reflective liquid crystal (LCOS: Liquid Crystal on Silicon). The spatial light modulator 105 can modulate the laser light L0 by appropriately setting a modulation pattern to be displayed on a liquid crystal layer. In the present embodiment, the laser light L0 traveling downward from the optical axis adjusting part 104 along the Z direction enters into the laser processing head H, is reflected by a mirror M1, and then enters into the spatial light modulator 105. The spatial light modulator 105 modulates the laser light L0 entering in this manner while reflecting the laser light L0.

The converging part 106 is attached to the bottom wall of the laser processing head H. The converging part 106 converges the laser light L0 modulated by the spatial light modulator 105 on the wafer 20 supported by the support part 102. In the present embodiment, the laser light L0 reflected by the spatial light modulator 105 is reflected by the dichroic mirror M2 and enters into the converging part 106. The converging part 106 converges the laser light L0 entering in this manner on the wafer 20. The converging part 106 is configured by attaching a converging lens unit 161 to the bottom wall of the laser processing head H via a drive mechanism 162. The drive mechanism 162 moves the converging lens unit 161 along the Z direction by, for example, a driving force of a piezoelectric element.

In the laser processing head H, an imaging optical system (not illustrated) is disposed between the spatial light modulator 105 and the converging part 106. The imaging optical system constitutes a double-sided telecentric optical system in which the reflecting surface of the spatial light modulator 105 and the entrance pupil surface of the converging part 106 are in an imaging relation. Thus, an image of the laser light L0 on the reflecting surface of the spatial light modulator 105 (an image of the laser light L0 modulated by the spatial light modulator 105) is transferred (formed) to (on) the entrance pupil surface of the converging part 106. A pair of distance measuring sensors S1 and S2 are attached to the bottom wall of the laser processing head H to be located on both sides of the converging lens unit 161 in the X direction. Each of the distance measuring sensors S1 and S2 emits distance measurement light (for example, laser light) to a laser light entrance surface of the wafer 20 and detects the distance measurement light reflected by the laser light entrance surface to acquire displacement data of the laser light entrance surface.

The optical axis monitoring unit 107 is disposed in the laser processing head H. The optical axis monitoring unit 107 detects a portion of the laser light L0 transmitted through the dichroic mirror M2. The detection result by the optical axis monitoring unit 107 indicates, for example, a relation between the optical axis of the laser light L0 entering into the converging lens unit 161 and the optical axis of the converging lens unit 161. The visible image capturing unit 108A emits visible light V0 and acquires an image of the wafer 20 by the visible light V0 as an image. The visible image capturing unit 108A is disposed in the laser processing head H. The infrared image capturing unit 108B emits infrared light and acquires an image of the wafer 20 by the infrared light as an infrared image. The infrared image capturing unit 108B is attached to the side wall of the laser processing head H.

The movement mechanism 109 includes a mechanism that moves at least one of the laser processing head H and the support part 102 in the X direction, the Y direction, and the Z direction. The movement mechanism 109 drives at least one of the laser processing head H and the support part 102 by a driving force of a known driving device such as a motor so that a converging point C of the laser light L0 moves in the X direction, the Y direction, and the Z direction. The movement mechanism 109 includes a mechanism that rotates the support part 102. The movement mechanism 109 rotationally drives the support part 102 by a driving force of a known driving device such as a motor.

The management unit 150 includes a control unit 151, a user interface 152, and a storage unit 153. The control unit 151 controls the operation of each unit in the laser processing device 100. The control unit 151 is configured as a computer device including a processor, a memory, a storage, a communication device, and the like. In the control unit 151, the processor executes software (program) read into the memory or the like, and controls reading and writing of data in the memory and the storage, and communication by a communication device. The user interface 152 displays and inputs various types of data. The user interface 152 constitutes a graphical user interface (GUI) having a graphic-based operation system.

The user interface 152 includes, for example, at least one of a touch panel, a keyboard, a mouse, a microphone, a tablet terminal, a monitor, and the like. The user interface 152 can receive various inputs, for example, by a touch input, a keyboard input, a mouse operation, a voice input, and the like. The user interface 152 can display various types of information on a display screen. The user interface 152 corresponds to an input reception unit that receives an input and a display unit that can display a setting screen based on the received input. The storage unit 153 is, for example, a hard disk or the like, and stores various types of data.

In the laser processing device 100 configured as described above, if the laser light L0 is converged in the wafer 20, the laser light L is absorbed at a portion corresponding to the converging point C (at least a portion of a converging region) of the laser light L0, and thus a modified region 11 is formed in the wafer 20. The modified region 11 is a region in which the density, the refractive index, the mechanical strength, and other physical properties are different from those of the surrounding non-modified region. Examples of the modified region 11 include a melting treatment region, a crack region, a dielectric breakdown region, and a refractive index change region. The modified region 11 includes a plurality of modified spots 11s and a fracture extending from the plurality of modified spots 11s.

An operation of the laser processing device 100 when a modified region 11 is formed in the wafer 20 along a line 15 for cutting the wafer 20 will be described as an example.

First, the laser processing device 100 rotates the support part 102 such that the line 15 set on the wafer 20 is parallel to the X direction. The laser processing device 100 moves the support part 102 along each of the X direction and the Y direction based on an image (for example, an image of a functional element layer included in the wafer 20) acquired by the infrared image capturing unit 108B, such that the converging point C of the laser light L0 is located on the line 15 when viewed from the Z direction. The laser processing device 100 moves the laser processing head H (that is, the converging part 106) along the Z direction based on an image (for example, an image of the laser light entrance surface of the wafer 20) acquired by the visible image capturing unit 108A such that the converging point C of the laser light L0 is located on the laser light entrance surface (height set). The laser processing device 100 moves the laser processing head H along the Z direction by using the position thereof as a reference such that the converging point C of the laser light L0 is located at a predetermined depth from the laser light entrance surface.

The laser processing device 100 causes the light source 103 to emit the laser light L0 and moves the support part 102 along the X direction so that the converging point C of the laser light L0 moves relatively along the line 15. At this time, the laser processing device 100 operates the drive mechanism 162 of the converging part 106 based on the displacement data of the laser light entrance surface acquired by the distance measuring sensor located on the front side in a processing proceeding direction of the laser light L0 among the pair of distance measuring sensors S1 and S2, so that the converging point C of the laser light L0 is located at a predetermined depth from the laser light entrance surface.

As described above, one row of modified regions 11 is formed along the line 15 and at a predetermined depth from the laser light entrance surface of the wafer 20. When the laser light L0 is emitted from the light source 103 by a pulse oscillation method, a plurality of modified spots 11s are formed to be arranged in a row along the X direction. One modified spot 11s is formed by irradiation with the laser light L0 of one pulse. The modified region 11 in one row is a set of a plurality of modified spots 11s arranged in one row. Adjacent modified spots 11s may be connected to each other or separated from each other, depending on a pulse pitch of the laser light L0 (a value obtained by dividing the relative movement speed of the converging point C with respect to the wafer 20 by a repetition frequency of the laser light L0).

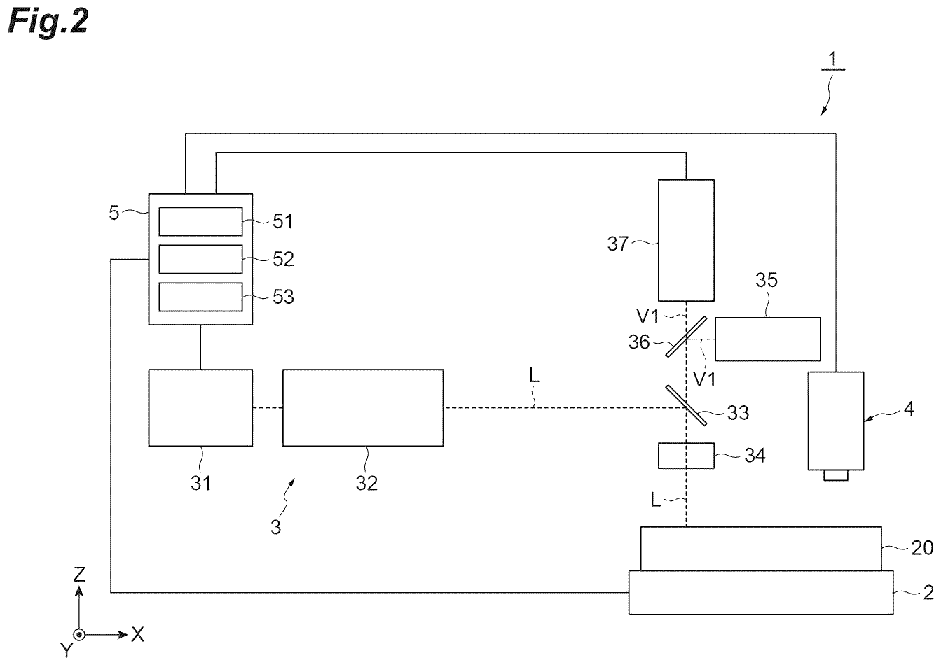

In the laser processing method in the embodiment, a street is irradiated with the laser light so that the surface layer of the street of the wafer 20 is removed. As a device that irradiates the street with the laser light so that the surface layer of the street of the wafer 20 is removed, for example, the laser processing device 1 illustrated in FIG. 2 can be used.

As illustrated in FIG. 2, a laser processing device 1 includes a support part 2, an irradiation unit 3, an image capturing unit 4, and a control unit 5. The laser processing device 1 is a device that performs grooving processing of removing a surface layer of a street of a wafer 20 by irradiating the street (details will be described later) of the wafer 20 with laser light L.

The support part 2 supports the wafer 20. The support part 2 holds the wafer 20, for example, by attracting the wafer 20 such that the surface of the wafer 20 including a street faces the irradiation unit 3 and the image capturing unit 4. As an example, the support part 2 can move along the X-direction and the Y-direction, respectively, and can rotate around an axis parallel to the Z-direction as a center line.

The irradiation unit 3 irradiates the street of the wafer 20 supported by the support part 2 with the laser light L. The irradiation unit 3 includes a light source 31, a shaping optical system 32, a dichroic mirror 33, and a converging part 34. The light source 31 emits laser light L. The shaping optical system 32 adjusts the laser light L emitted from the light source 31. As an example, the shaping optical system 32 includes at least one of an attenuator that adjusts the output of the laser light L, a beam expander that expands the diameter of the laser light L, and a spatial light modulator that modulates the phase of the laser light L. When the shaping optical system 32 includes the spatial light modulator, the shaping optical system may include an imaging optical system constituting a double-sided telecentric optical system in which the modulation surface of the spatial light modulator and the incident pupil surface of the converging part 34 have an imaging relationship. The dichroic mirror 33 reflects the laser light L emitted from the shaping optical system 32 and enters the laser light L into the converging part 34. The converging part 34 converges the laser light L reflected by the dichroic mirror 33 on the street of the wafer 20 supported by the support part 2.

The irradiation unit 3 further includes a light source 35, a half mirror 36, and an imaging element 37. The light source 35 emits visible light V1. The half mirror 36 reflects the visible light V1 emitted from the light source 35 and enters the visible light V1 into the converging part 34. The dichroic mirror 33 transmits the visible light V1 between the half mirror 36 and the converging part 34. The converging part 34 converges the visible light V1 reflected by the half mirror 36 on the street of the wafer 20 supported by the support part 2. The imaging element 37 detects the visible light V1 that is reflected by the street of the wafer 20 and transmitted through the converging part 34, the dichroic mirror 33, and the half mirror 36. In the laser processing device 1, the control unit moves the converging part 34 in the Z direction based on the detection result by the imaging element 37, for example, so that the converging point of the laser light L is located on the street of the wafer 20.

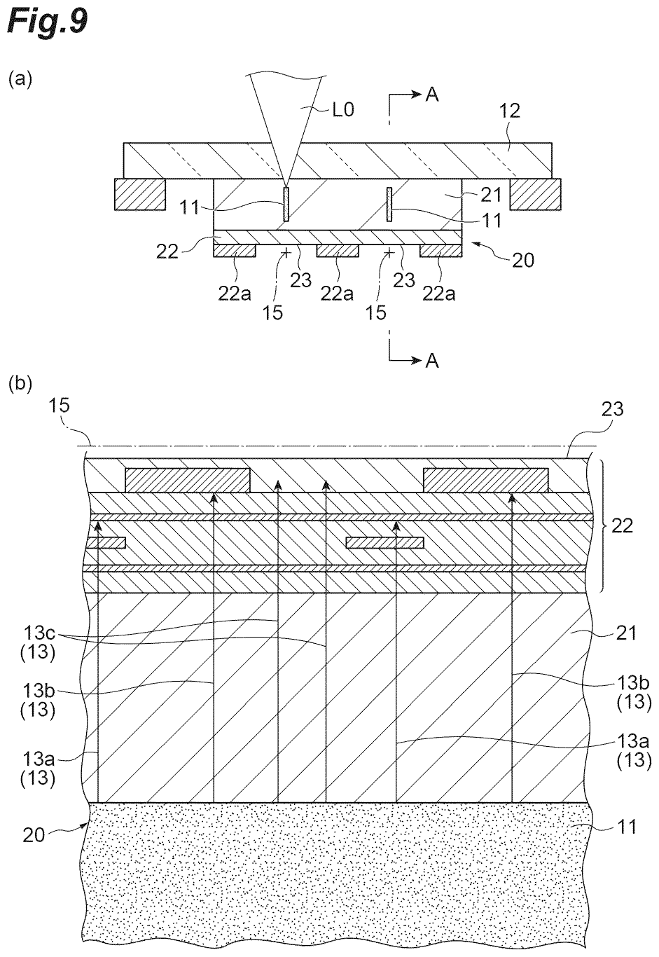

The image capturing unit 4 acquires image data of the street of the wafer 20 supported by the support part 2. The image capturing unit 4 is an internal observation camera that observes the inside of the wafer in which the modified region 11 is formed by the laser processing device 100. The image capturing unit 4 captures image data for acquiring fracture extension information regarding extension of a fracture 13 (see FIG. 9(b)) extending from the modified region 11. The image capturing unit 4 detects the tip of the fracture 13 extending from the modified region 11. The image capturing unit 4 emits infrared light to the wafer 20 and acquires an image of the wafer 20 by the infrared light as image data. As the image capturing unit 4, an InGaAs camera can be used.

The control unit 5 controls the operation of each unit in the laser processing device 1. The control unit 5 includes a processing unit 51, a storage unit 52, and an input reception unit 53. The processing unit 51 is a computer device including a processor, a memory, a storage, a communication device, and the like. In the processing unit 51, the processor executes software (program) read into the memory or the like, and controls reading and writing of data in the memory and the storage, and communication by a communication device. The storage unit 52 is, for example, a hard disk or the like, and stores various types of data. The input reception unit 53 is an interface unit that receives inputs of various types of data from an operator. As an example, the input reception unit 53 is at least one of a keyboard, a mouse, and a graphical user interface (GUI).

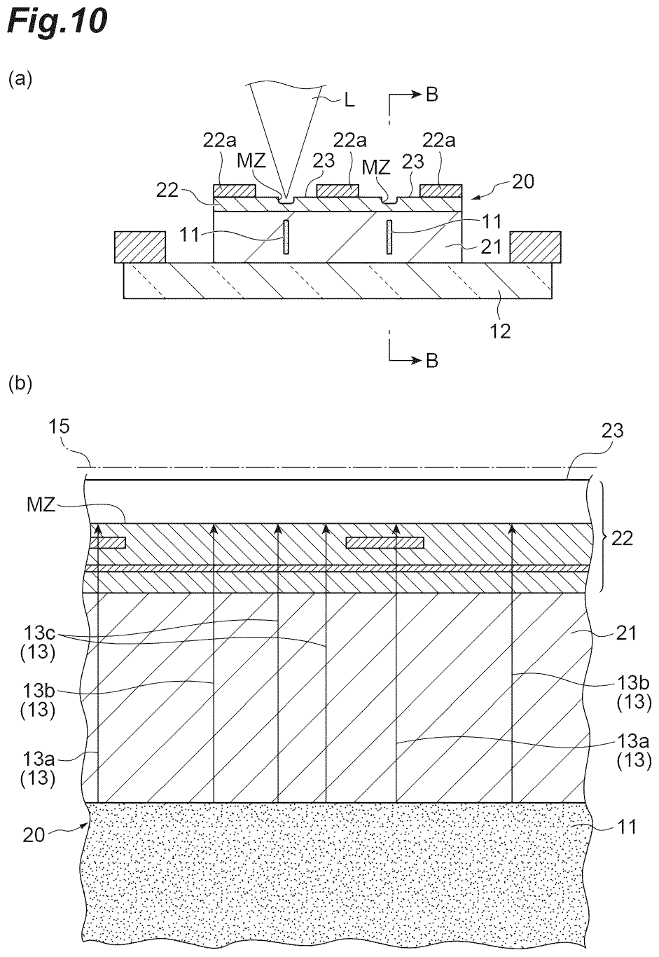

The laser processing device 1 performs grooving processing of removing the surface layer of each street by irradiating each street with laser light L. Specifically, the control unit 5 controls the irradiation unit 3 such that each street of the wafer 20 supported by the support part 2 is irradiated with the laser light L, and the control unit 5 controls the support part 2 such that the laser light L relatively moves along each street. At this time, the control unit 5 irradiates the street with the laser light L such that the surface layer of the street is removed, and a fracture extending from the modified region 11 reaches the bottom surface of a groove (recess) formed by removing the surface layer of the street along the line (see FIG. 10) (details will be described later).

[Configuration of Wafer]

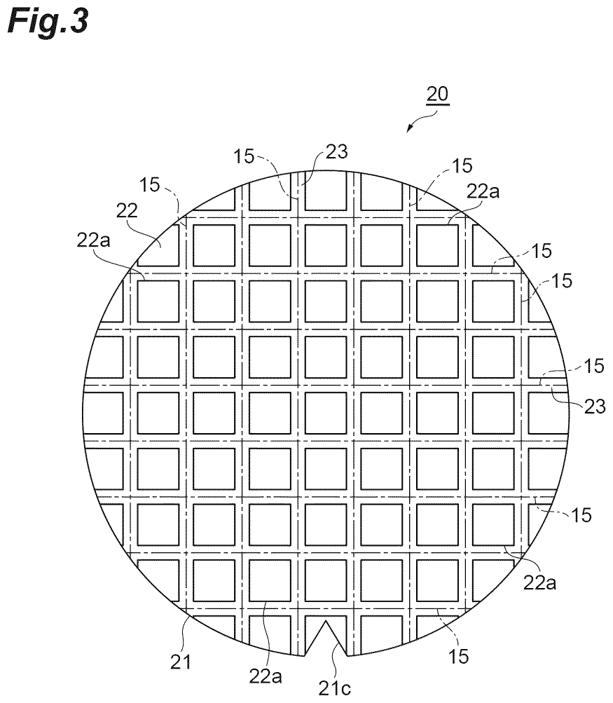

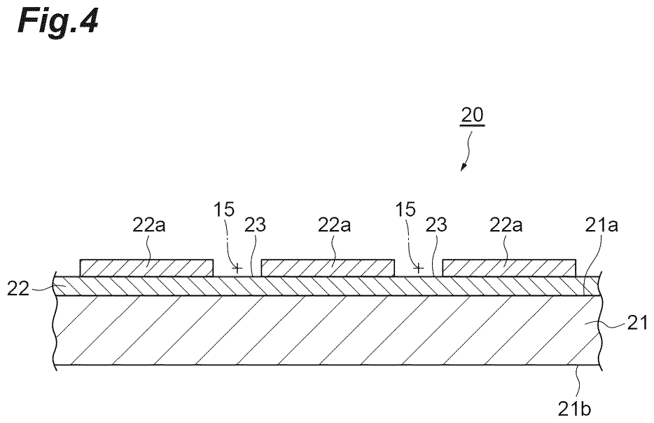

As illustrated in FIGS. 3 and 4, the wafer 20 includes a semiconductor substrate 21 and a functional element layer 22. The semiconductor substrate 21 has a front surface 21a and a back surface 21b. The semiconductor substrate 21 is, for example, a silicon substrate. A notch 21c indicating a crystal orientation is provided in the semiconductor substrate 21. The semiconductor substrate 21 may be provided with an orientation flat instead of the notch 21c. The functional element layer 22 is formed on the front surface 21a of the semiconductor substrate 21. The functional element layer 22 includes a plurality of functional elements 22a. The plurality of functional elements 22a are two-dimensionally disposed along the front surface 21a of the semiconductor substrate 21. Each of the functional elements 22a is, for example, a light receiving element such as a photodiode, a light emitting element such as a laser diode, a circuit element such as a memory, or the like. Each of the functional elements 22a may be configured three-dimensionally by stacking a plurality of layers.

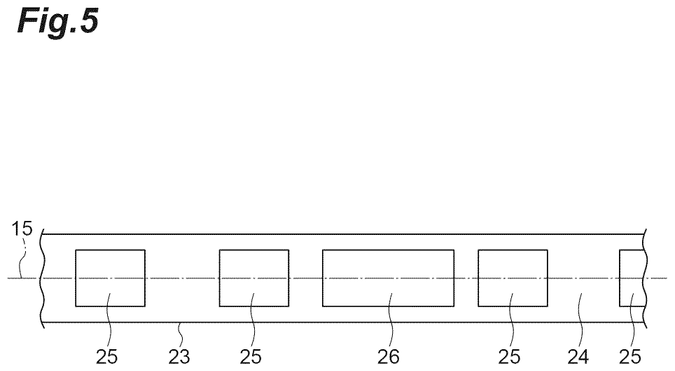

A plurality of streets 23 are formed on the wafer 20. The plurality of streets 23 are regions exposed to the outside between the adjacent functional elements 22a. That is, the plurality of functional elements 22a are disposed to be adjacent to each other via the street 23. As an example, the plurality of streets 23 extend in a lattice shape so as to pass between the adjacent functional elements 22a with respect to the plurality of functional elements 22a arranged in a matrix. As illustrated in FIG. 5, an insulating film 24 and a plurality of metal structures 25 and 26 are formed on the surface layer of the street 23. The insulating film 24 is, for example, a Low-k film. Each of the metal structures 25 and 26 is, for example, a metal pad. The metal structure 25 and the metal structure 26 are different from each other in at least one of a thickness, an area, and a material, for example.

As illustrated in FIGS. 3 and 4, the wafer 20 is scheduled to be cut along each of a plurality of lines 15 for each functional element 22a (that is, scheduled to be chipped for each functional element 22a). Each line 15 passes through each street 23 when viewed from a thickness direction of the wafer 20. As an example, each line 15 extends to pass through the center of each street 23 when viewed from the thickness direction of the wafer 20. Each line 15 is a virtual line set on the wafer 20 by the laser processing devices 1 and 100. Each line 15 may be a line actually drawn on the wafer 20.

[Laser Processing Method]

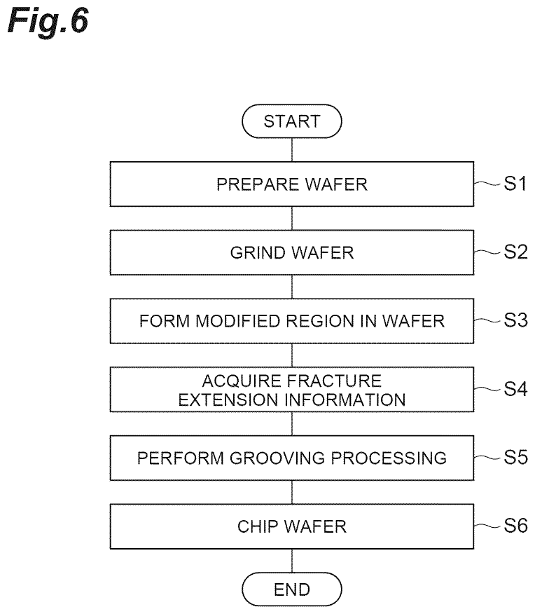

A laser processing method according to a first embodiment using the laser processing device 100 and the laser processing device 1 will be described with reference to a flowchart illustrated in FIG. 6.

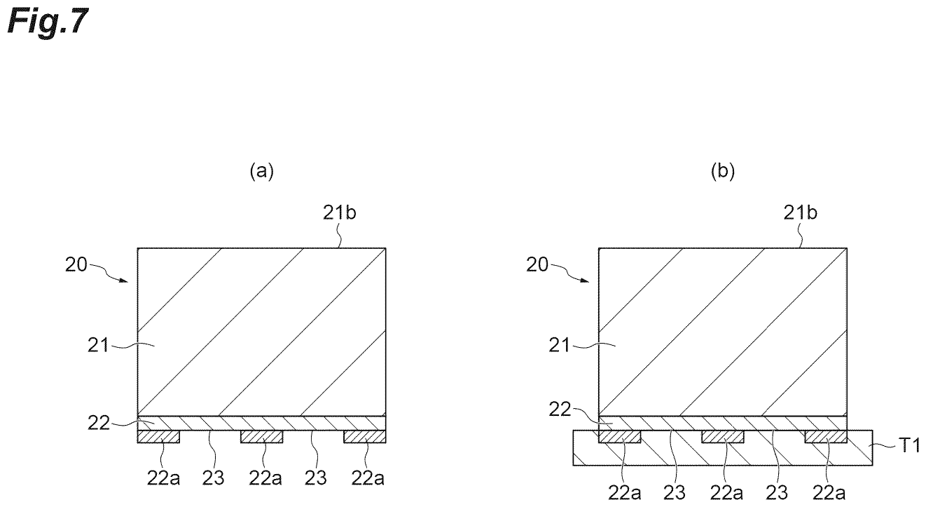

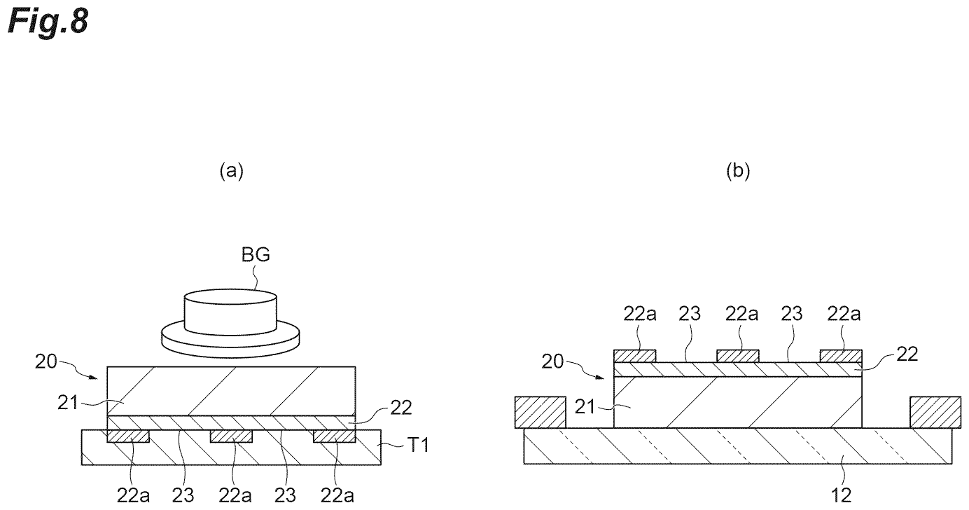

First, as illustrated in FIG. 7(a), a wafer 20 is prepared (Step S1: first step). As illustrated in FIG. 7(b), a grinding tape T1 is attached to the surface of the wafer 20 on a functional element 22a side. As illustrated in FIG. 8(a), a grinding device having a grindstone BG grinds the back surface 21b side of a semiconductor substrate 21 of the wafer 20, and thins the wafer 20 to a desired thickness (Step S2: grinding step). As illustrated in FIG. 8(b), the grinding tape T1 is replaced with a transparent dicing tape 12. The transparent dicing tape 12 is also referred to as an expanded film.

Then, as illustrated in FIGS. 9(a) and 9(b), in the laser processing device 100, a modified region 11 is formed in the wafer 20 along each line 15 by irradiating the wafer 20 with laser light L0 along each line 15 (Step S3: second step). The upper side in FIG. 9(a) corresponds to the lower side in FIG. 9(b).

In Step S3, in a state where the transparent dicing tape 12 is attached to the back surface 21b of the semiconductor substrate 21, the wafer 20 is irradiated with the laser light L0 by aligning a converging point of the laser light L0 with the inside of the semiconductor substrate 21 via the transparent dicing tape 12. The laser light L0 has transparency to the transparent dicing tape 12 and the semiconductor substrate 21. When the laser light L0 is converged in the semiconductor substrate 21, the laser light L0 is absorbed in a portion corresponding to the converging point of the laser light L0, and the modified region 11 is formed in the semiconductor substrate 21. The modified region 11 has a characteristic that fractures 13 easily extend from the modified region 11 to the incident side of the laser light L0 and the opposite side of the incident side.

In Step S3, the modified region 11 is formed in the wafer 20 along the line 15 such that a fracture 13 extending from the modified region 11 does not reach the street 23. Processing conditions for forming the modified region 11 in Step S3 are not particularly limited, and can be set based on various known knowledges. The processing conditions may be appropriately input via the user interface 152 (see FIG. 1).

Then, in the laser processing device 1, the image capturing unit 4 acquires image data of each street 23 of the wafer 20 in a state where the wafer 20 is supported by the support part 2. The control unit 5 acquires fracture extension information of the fracture 13 based on the image capturing result of the image capturing unit 4 (Step S4: information acquisition step). The fracture extension information includes information regarding the distance of the tip of the fracture 13 to the street 23. The fracture extension information may include information regarding whether or not the fracture 13 has reached the street 23. The fracture extension information may include information regarding the extension amount of the fracture 13. In the fracture extension information, various types of information regarding extension of the fracture 13 are associated with, for example, each position in the X direction and the Y direction of each street 23. The acquired fracture extension information is stored in the storage unit 52 of the control unit 5.

Then, as illustrated in FIGS. 10(a) and 10(b), in the laser processing device 1, grooving processing is performed on the wafer 20 (Step S5) (third step). In Step S5, the control unit 5 controls the irradiation unit 3 such that each street 23 of the wafer 20 supported by the support part 2 is irradiated with the laser light L, and the control unit 5 controls the support part 2 such that the laser light L relatively moves along each street 23. At this time, the control unit 5 irradiates the street 23 with the laser light L based on the fracture extension information such that the surface layer of the street 23 is removed, and the fracture 13 reaches the bottom surface of a groove (recess) MZ formed by removing the surface layer of the street 23 along the line 15.

For example, in Step S5 described above, the removal depth (the depth of the groove MZ) of the surface layer of the street 23 is determined based on the fracture extension information so that even the fracture 13 having the smallest extension amount is exposed from the bottom surface of the groove MZ. Then, along the line 15, the street 23 is irradiated with the laser light L under the processing condition that the surface layer of the street 23 is removed at the determined removal depth, and the groove MZ is formed in the street 23.

For example, in Step S5 described above, in the example illustrated in FIG. 9(b), the depth of the groove MZ that causes a fracture 13a to be exposed to the bottom surface of the groove MZ is set based on the distance from the street 23 to the fracture 13a having a tip farthest from the street 23 among fractures 13a, 13b, and 13c having different extension amounts from the modified region 11. As illustrated in FIG. the surface layer of the street 23 is removed so that the groove MZ having the set depth is formed. As a result, all of the fractures 13a, 13b, and 13c reach the bottom surface of the groove MZ. The processing condition of grooving processing is not particularly limited, and can be set based on various known knowledges. The processing conditions may be appropriately input via the input reception unit 53 (see FIG. 2).

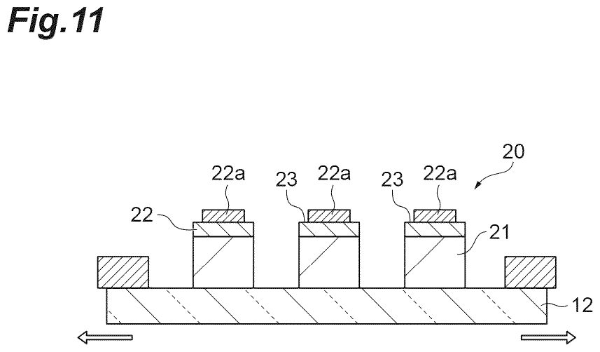

Then, as illustrated in FIG. 11, in an expanding device (not illustrated), the transparent dicing tape 12 is expanded to extend the fracture in the thickness direction of the wafer 20 from the modified region 11 formed in the semiconductor substrate 21 along each line 15, and to chip the wafer 20 for each functional element 22a (Step S6).

As described above, in the laser processing method in the present embodiment, the modified region 11 is always formed in the wafer 20 before the grooving processing. In other words, grooving processing is always performed after the modified region 11 is formed in the wafer 20. That is, after the modified region 11 is formed along the line 15 in the wafer 20 in Step S3, grooving processing of removing the surface layer of the street 23 is performed in Step S5. In the grooving processing, the fracture 13 extending from the modified region 11 in the wafer 20 formed in Step S3 reaches the bottom surface of the groove MZ formed by removing the surface layer of the street 23, along the line 15. Therefore, it is possible to reliably chip the wafer 20 for each functional element 22a by the fracture 13.

In the laser processing method in the present embodiment, in Step S2, the wafer 20 is ground and thinned. This makes it possible to obtain a wafer 20 having a desired thickness.

In the laser processing method in the present embodiment, Step S2 being a grinding step is performed after Step S1 of preparing the wafer and before Step S3 of forming the modified region 11 in the wafer 20. For example, when the prepared wafer 20 is thicker than a predetermined thickness, there is a possibility that it is difficult to form the modified region 11 in the wafer 20. In this regard, by performing the grinding step before Step S3, it is possible to form the modified region 11 in the thinned wafer 20 even when the prepared wafer 20 is thicker than the predetermined thickness. Thus, it is possible to suppress the difficulty in forming the modified region 11 in the wafer 20.

The laser processing method in the present embodiment includes Step S4 of acquiring fracture extension information described above before grooving processing is performed. In the grooving processing, the street 23 is irradiated with the laser light L based on the acquired fracture extension information such that the surface layer of the street 23 is removed and the fracture 13 reaches the bottom surface of the groove MZ along the line 15. In this case, it is possible to acquire the fracture extension information and to perform grooving processing by using the fracture extension information.

In the laser processing method in the present embodiment, in Step S4 of acquiring the fracture extension information, the fracture extension information is acquired based on an image capturing result obtained by the image capturing unit 4 capturing an image of the wafer 20 after Step S3 in which the modified region is formed. In this case, it is possible to acquire the fracture extension information from the image capturing result of the image capturing unit 4.

In the laser processing method in the present embodiment, in Step S3, the modified region 11 is formed in the wafer 20 along the line 15 such that the fracture 13 does not reach the street 23. For example, when the wafer 20 after Step S3 is transported, if the fracture 13 reaches the street 23, there is a possibility that the wafer 20 warps due to the fracture 13, and an unintended crack is likely to occur in the wafer 20. In this regard, by preventing the fracture 13 from reaching the street 23 in Step S3, it is possible to suppress the occurrence of an unintended crack in the wafer 20.

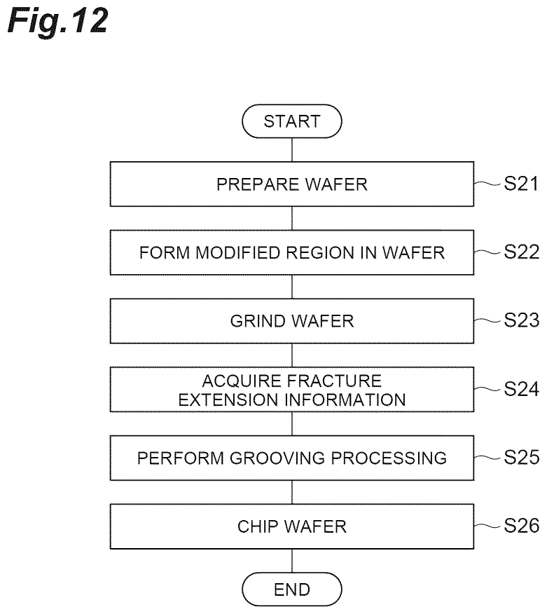

Next, a laser processing method according to a second embodiment using the laser processing device 100 and the laser processing device 1 will be described with reference to a flowchart illustrated in FIG. 12. In the following description, description of contents overlapping with the first embodiment will be appropriately omitted.

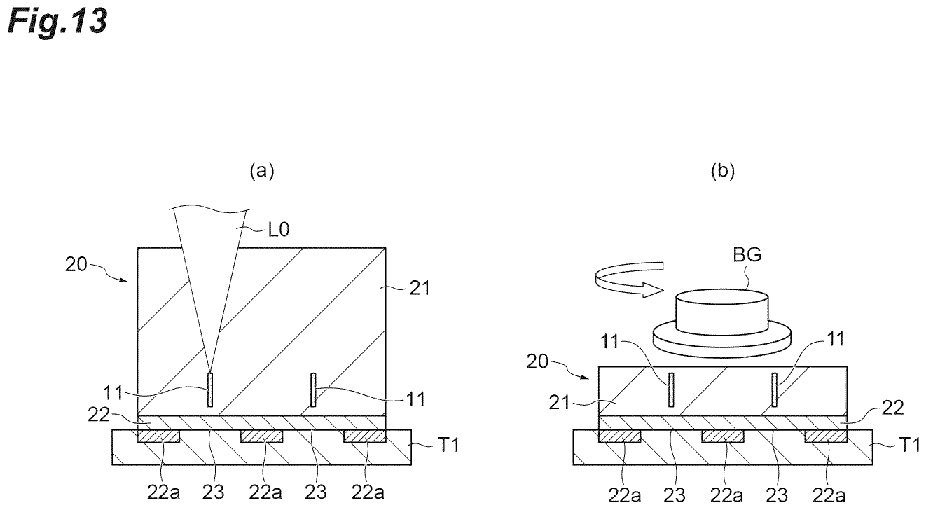

First, a wafer 20 is prepared (Step S21: first step). A grinding tape T1 is attached to the surface of the wafer 20 on a functional element 22a side. As illustrated in FIG. 13(a), in the laser processing device 100, a modified region 11 is formed in the wafer 20 along each line 15 by irradiating the wafer 20 with laser light L0 along each line 15 (Step S22: second step).

In Step S22, the wafer 20 is irradiated with laser light L0 by aligning a converging point of the laser light L0 with the inside of a semiconductor substrate 21 from the back surface 21b side in a state where the grinding tape T1 is attached to the functional element 22a of the wafer 20. In Step S22, the modified region 11 is formed in the wafer along the line 15 such that a fracture 13 extending from the modified region 11 does not reach the street 23.

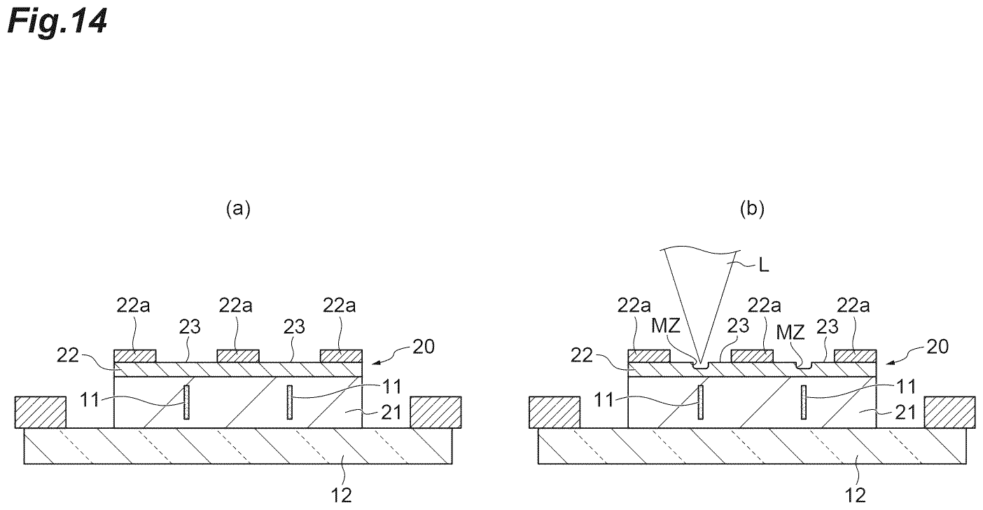

Then, as illustrated in FIG. 13(b), a grinding device having a grindstone BG grinds the back surface 21b side of a semiconductor substrate 21 of the wafer 20, and thins the wafer 20 to a desired thickness (Step S23: grinding step). As illustrated in FIG. 14(a), the grinding tape T1 is replaced with a transparent dicing tape 12.

Then, in the laser processing device 1, the image capturing unit 4 acquires image data of each street 23 of the wafer 20 in a state where the wafer 20 is supported by the support part 2. The control unit 5 acquires fracture extension information of the fracture 13 based on the image capturing result of the image capturing unit 4 (Step S24: information acquisition step). As illustrated in FIG. 14(b), in the laser processing device 1, grooving processing is performed on the wafer 20 (Step S25) (third step). In Step S25, the street 23 is irradiated with the laser light L based on the fracture extension information such that the surface layer of the street 23 is removed, and the fracture 13 reaches the bottom surface of a groove MZ formed by removing the surface layer of the street 23 along the line 15.

Then, in an expanding device, the transparent dicing tape 12 is expanded to extend the fracture in the thickness direction of the wafer 20 from the modified region 11 formed in the semiconductor substrate 21 along each line 15, and to chip the wafer 20 for each functional element 22a (Step S26).

As described above, also in the laser processing method in the present embodiment, similarly to the above-described embodiment, an effect that it is possible to reliably chip the wafer 20 for each functional element 22a is exhibited. In the laser processing method in the present embodiment, Step S23 being the grinding step is performed after Step S22 of forming the modified region 11 in the wafer 20 and before Step S25 related to the grooving processing. For example, when the wafer in which the modified region 11 is formed is transported, if the thickness of the wafer 20 is thin, there is a possibility that an unintended crack is likely to occur in the wafer 20. In this regard, by performing the grinding step after Step S22, it is possible to transport the wafer 20 in which the modified region 11 is formed therein, before being thinned, and it is possible to suppress the occurrence of an unintended crack in the wafer 20.

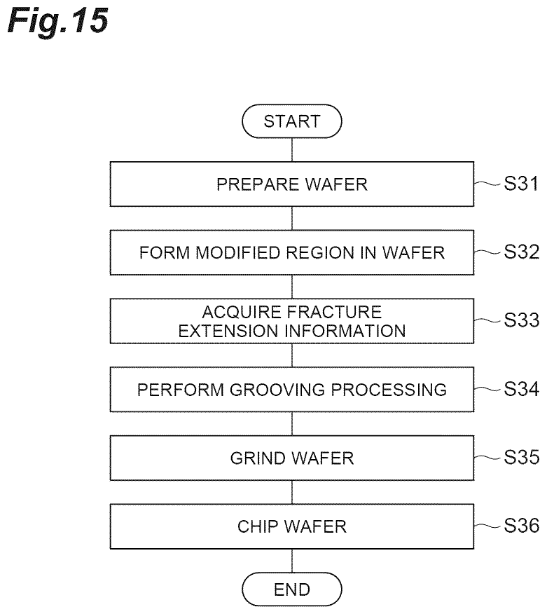

Next, a laser processing method according to a third embodiment using the laser processing device 100 and the laser processing device 1 will be described with reference to a flowchart illustrated in FIG. 15. In the following description, description of contents overlapping with the first embodiment will be appropriately omitted.

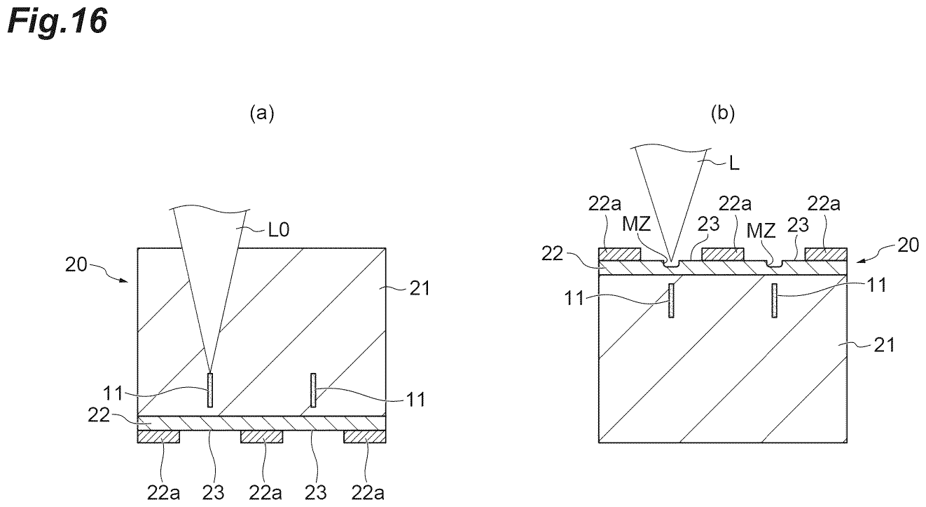

First, a wafer 20 is prepared (Step S31: first step). As illustrated in FIG. 16(a), in the laser processing device 100, a modified region 11 is formed in the wafer 20 along each line 15 by irradiating the wafer 20 with laser light L0 along each line 15 (Step S32: second step). In Step S32, the wafer 20 is irradiated with the laser light L0 by aligning a converging point of the laser light L0 with the inside of a semiconductor substrate 21 from the back surface 21b side. In Step S32, the modified region 11 is formed in the wafer 20 along the line 15 such that a fracture 13 extending from the modified region 11 does not reach the street 23. In Step S32, for example, when the surface of the wafer 20 on the functional element 22a side has large unevenness, a tape material may be attached to the surface, or the wafer 20 may be attracted by the support part 102 that supports the wafer 20, in accordance with the unevenness.

Then, in the laser processing device 1, the image capturing unit 4 acquires image data of each street 23 of the wafer 20 in a state where the wafer 20 is supported by the support part 2. The control unit 5 acquires fracture extension information of the fracture 13 based on the image capturing result of the image capturing unit 4 (Step S33: information acquisition step). Then, as illustrated in FIG. 16(b), in the laser processing device 1, grooving processing is performed on the wafer 20 (Step S34) (third step). In Step S34, the street 23 is irradiated with the laser light L based on the fracture extension information such that the surface layer of the street 23 is removed, and the fracture 13 reaches the bottom surface of a groove MZ formed by removing the surface layer of the street 23 along the line 15.

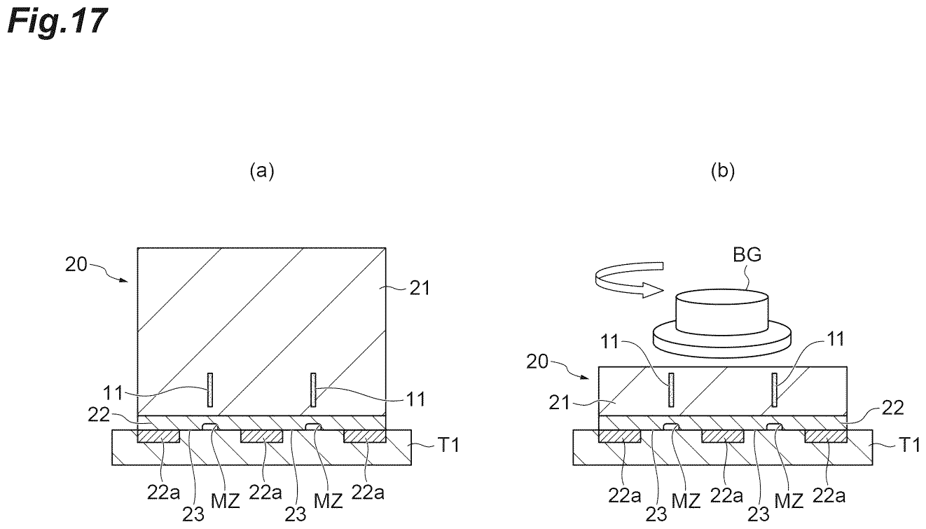

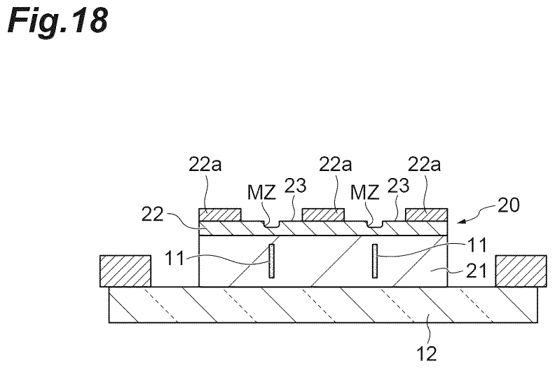

Then, as illustrated in FIG. 17(a), a grinding tape T1 is attached to the surface of the wafer 20 on a functional element 22a side. As illustrated in FIG. 17(b), a grinding device having a grindstone BG grinds the back surface 21b side of a semiconductor substrate 21 of the wafer 20, and thins the wafer 20 to a desired thickness (Step S35: grinding step). As illustrated in FIG. 18, the grinding tape T1 is replaced with a transparent dicing tape 12.

Then, in an expanding device, the transparent dicing tape 12 is expanded to extend the fracture in the thickness direction of the wafer 20 from the modified region 11 formed in the semiconductor substrate 21 along each line 15, and to chip the wafer 20 for each functional element 22a (Step S36).

As described above, also in the laser processing method in the present embodiment, similarly to the above-described embodiment, an effect that it is possible to reliably chip the wafer 20 for each functional element 22a is exhibited. In the laser processing method in the present embodiment, Step S23 being the grinding step is performed after Step S34 related to the grooving processing. For example, when the wafer 20 after the grooving processing is transported, if the thickness of the wafer 20 is thin, there is a possibility that an unintended crack is likely to occur in the wafer 20. In this regard, by performing the grinding step after Step S34, it is possible to transport the wafer 20 before the wafer 20 after grooving processing is thinned, and it is possible to suppress the occurrence of an unintended crack in the wafer 20.

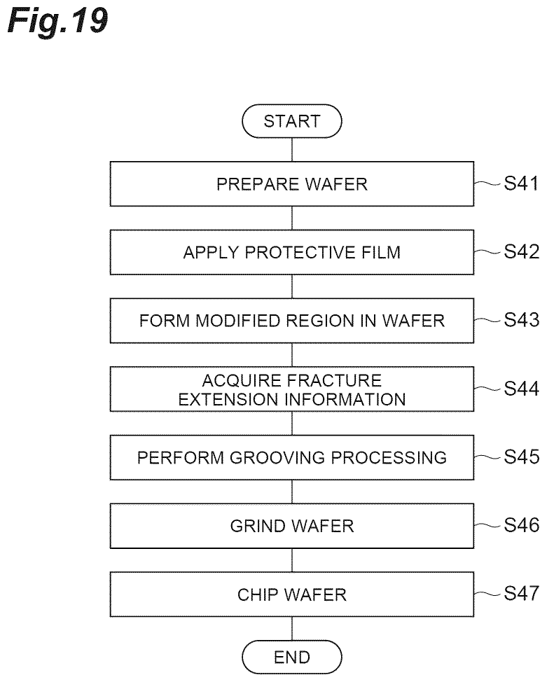

Next, a laser processing method according to a fourth embodiment using the laser processing device 100 and the laser processing device 1 will be described with reference to a flowchart illustrated in FIG. 19. In the following description, description of contents overlapping with the third embodiment will be appropriately omitted.

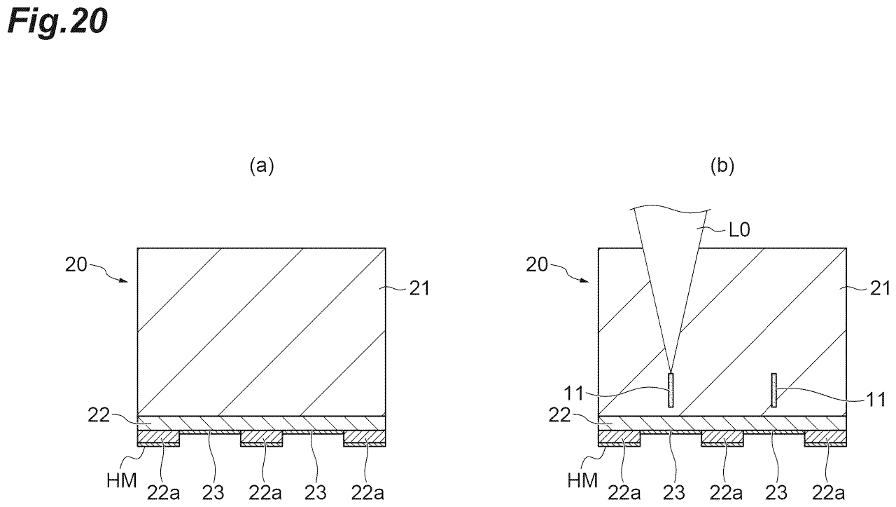

First, a wafer 20 is prepared (Step S41: first step). As illustrated in FIG. 20(a), a protective film HM is applied onto the surface on the functional element 22a side (at least on the street 23 in the wafer 20) (Step S42: protective film applying step). The protective film HM is not particularly limited, and various protective films for protecting the wafer can be used.

As illustrated in FIG. 20(b), in the laser processing device 100, a modified region 11 is formed in the wafer 20 along each line 15 by irradiating the wafer 20 with laser light L0 along each line 15 (Step S43: second step). In Step S43, the wafer 20 is irradiated with laser light L0 by aligning a converging point of the laser light L0 with the inside of a semiconductor substrate 21 from the back surface 21b side in a state where the grinding tape T1 is attached to the functional element 22a of the wafer 20. In Step S43, the modified region 11 is formed in the wafer 20 along the line 15 such that a fracture 13 extending from the modified region 11 does not reach the street 23.

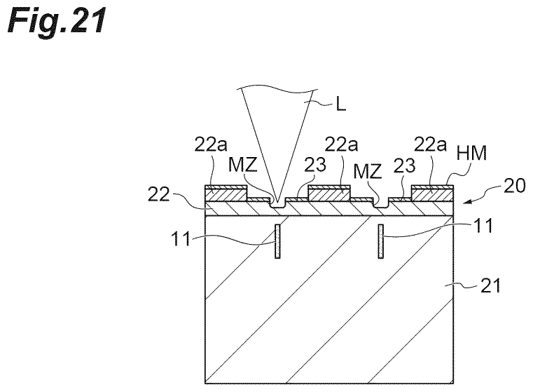

Then, in the laser processing device 1, the image capturing unit 4 acquires image data of each street 23 of the wafer 20 in a state where the wafer 20 is supported by the support part 2. The control unit 5 acquires fracture extension information of the fracture 13 based on the image capturing result of the image capturing unit 4 (Step S44: information acquisition step). As illustrated in FIG. 21, in the laser processing device 1, grooving processing is performed on the wafer 20 (Step S45) (third step). In Step S45, the street 23 is irradiated with the laser light L based on the fracture extension information such that the surface layer of the street 23 is removed, and the fracture 13 reaches the bottom surface of a groove MZ formed by removing the surface layer of the street 23 along the line 15.

Then, the protective film HM is removed. A timing of removing the protective film HM may be any timing after Step S45 described above. A grinding tape T1 is attached to the surface of the wafer 20 on a functional element 22a side. A grinding device having a grindstone BG grinds the back surface 21b side of a semiconductor substrate 21 of the wafer 20, and thins the wafer 20 to a desired thickness (Step S46: grinding step). The grinding tape T1 is replaced with a transparent dicing tape 12.

Then, in an expanding device, the transparent dicing tape 12 is expanded to extend the fracture in the thickness direction of the wafer 20 from the modified region 11 formed in the semiconductor substrate 21 along each line 15, and to chip the wafer 20 for each functional element 22a (Step S47).

As described above, also in the laser processing method in the present embodiment, similarly to the above-described embodiment, an effect that it is possible to reliably chip the wafer 20 for each functional element 22a is exhibited. In the laser processing method in the present embodiment, the protective film HM is applied onto at least the street 23 of the wafer 20 before Step S43 in which the modified region 11 is formed in the wafer 20. In this case, since it is possible to make the reflectance of the street 23 be constant by the protective film HM, it is possible to accurately acquire the fracture extension information in Step S44. The formation of the modified region 11 in Step S43 is not affected even though the protective film HM is provided.

### Modification Examples

The present disclosure is not limited to the above embodiment.

In the above embodiments, the fracture extension information may include information regarding whether or not the fracture 13 has reached the street 23, as described above. In this case, in the grooving processing, it is possible to perform the grooving processing by using the information regarding whether or not the fracture 13 has reached the street 23.

For example, in the grooving processing, only a region not reached by the fracture 13 along the line 15 in the street 23 may be irradiated with the laser light L based on the fracture extension information including the information regarding whether or not the fracture 13 reaches the street 23, such that the surface layer of the street 23 is removed and the fracture 13 reaches the bottom surface of the groove MZ along the line 15. As a result, the grooving processing is performed only in the region not reached by the fracture 13 along the line in the street 23. It is possible to efficiently perform grooving processing. In this case, when the protective film HM is applied similarly to the fourth embodiment, the fracture 13 is exposed to the street 23 through the protective film HM after the modified region 11 is formed in the wafer 20. Since the reflectance becomes constant by providing the protective film HM, it is easy to determine whether or not the fracture 13 has reached the street 23.

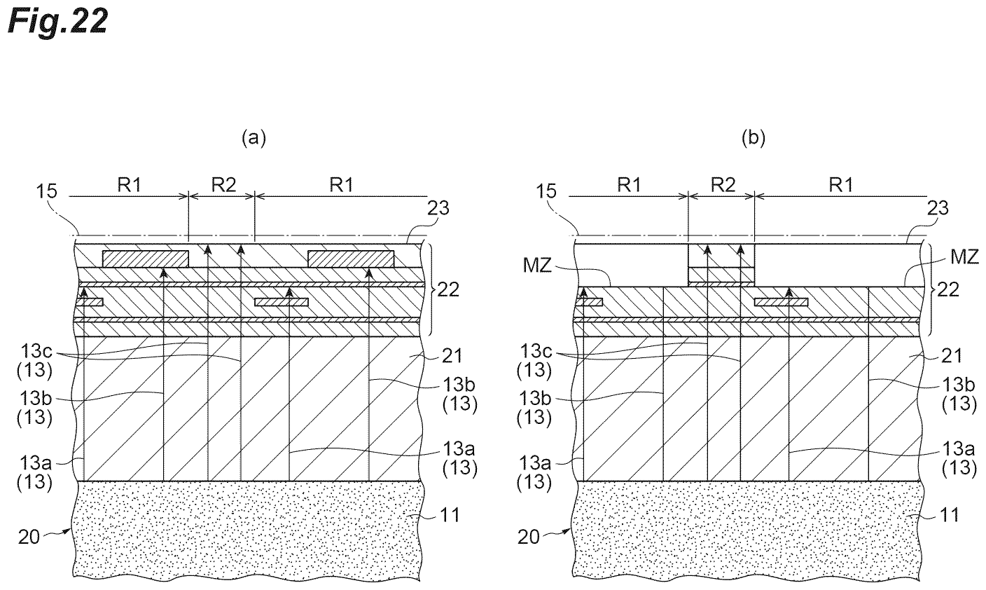

In the example illustrated in FIG. 22(a), the fracture extension information includes information indicating that “the fracture 13 extending from the modified region 11 does not reach the street 23 along the line 15 in a first region R1, and reaches the street 23 along the line 15 in a second region R2″. The first region R1 is a region corresponding to a metal structure 26 (see FIG. 5) in each street 23, and the second region R2 is a region other than the first region R1 in each street 23. In this case, in the grooving processing, only the first region R1 of the street 23 may be irradiated with the laser light L, and the second region R2 of the street 23 may not be irradiated with the laser light L. Specifically, the control unit 5 may control the irradiation unit 3 such that the output of the laser light L is turned ON when the laser light L relatively moves on the first region R1, and the output of the laser light L is turned OFF when the laser light L relatively moves on the second region R2. As a result, as in the example illustrated in FIG. 22(b), the surface layer (that is, metal structure 26) of the street 23 is removed, and the fracture 13 has reached the bottom surface of the groove MZ along the line 15 in the first region R1 of each street 23, but the surface layer of the street 23 is left in the second region R2 of each street 23.

The that “the fracture 13 extending from the modified region 11 reaches the street 23 along the line 15” means that “the fracture 13 extending from the modified region 11 reaches the street 23, and the meandering of each of both edges 23a of the cut street 23 falls within a predetermined width (a predetermined width in a direction perpendicular to the line 15)”. In addition, the phase that “the fracture 13 extending from the modified region 11 does not reach the street 23 along the line means that “the meandering of each of both edges 23a of the cut street 23 exceeds a predetermined width even though the fracture 13 extending from the modified region 11 does not reach the street 23 or the fracture 13 extending from the modified region 11 reaches the street 23”. The predetermined width is, for example, about 10 μm.

Although the above embodiments include the information acquisition step of acquiring the fracture extension information in the laser processing device 1, the fracture extension information may be acquired in the laser processing device 100, or the fracture extension information may be acquired by another device. The above embodiments may not include the information acquisition step. In this case, the fracture extension information acquired in advance may be stored in the storage unit 52. For example, the fracture extension information may be information checked in advance on a test wafer. In the above embodiments, the groove MZ is formed by grooving processing, but a hole or a concave portion may be formed instead of the groove MZ, and in short, a recess may be formed.

In the above embodiments, for example, since there is a predetermined correlation between the height of the street 23 and the light amount in the extension of the fracture 13, the fracture extension information may include information regarding the height of the street 23 and the light amount. For example, the laser processing device 1 may include a distance measuring unit instead of or in addition to the image capturing unit 4, and the distance measuring unit may acquire information regarding the height of the street 23. As the distance measuring unit, for example, a laser displacement meter of as a triangulation type, a spectral interference type, a multi-color confocal type, a monochromatic confocal type, or the like can be used.

In the above embodiments, the image capturing unit 4 may include a camera that acquires image data of a street of the wafer 20 by using visible light. In the above embodiments, information for controlling the irradiation condition (laser ON/OFF control, laser power) of the laser light L in each region of the street 23 can be created by using the image obtained by capturing an image of at least the surface layer of the street 23 after cutting and the perspective image using infrared rays. Then, the grooving processing can be controlled based on the created information. In the above embodiments, the surface layer of the street 23 may be removed by scanning the street 23 with the laser light L a plurality of times. In the above embodiments, only the support part 102 may be controlled, only the laser processing head H may be controlled, or both the support part 102 and the laser processing head H may be controlled, such that the laser light L0 relatively moves along each line 15. In the above embodiments, only the support part 2 may be controlled, only the irradiation unit 3 may be controlled, or both the support part 2 and the irradiation unit 3 may be controlled, such that the laser light L relatively moves along each street 23.

In the above embodiments, the grooving processing (third step) is performed such that the fracture 13 extending from the modified region 11 reaches the bottom surface of the groove MZ along the line 15, but the present invention is not limited thereto. For example, the grooving processing may be performed such that the fracture 13 does not reach the bottom surface of the groove MZ along the line 15 immediately after the grooving processing, and the fracture 13 reaches the bottom surface of the groove MZ along the line 15 after the subsequent fourth step.

That is, the laser processing method according to one aspect includes a first step of preparing a wafer 20 including a plurality of functional elements 22a disposed to be adjacent to each other via a street 23, a second step of, after the first step, forming a modified region 11 in the wafer 20 along a line 15 passing through the street 23, a third step of, after the second step, irradiating the street 23 with laser light L such that a surface layer of the street 23 is removed, and a fourth step of processing the wafer 20 after the third step. In the third step, the street 23 is irradiated with the laser light L such that a fracture 13 extending from the modified region 11 reaches a bottom surface of a groove MZ formed by removing the surface layer of the street 23, along the line 15 after the fourth step. Such processing can be realized by grasping, in advance, the length of the fracture 13 after the formation of the modified region 11 and before the grooving processing, and the extension amount of the fracture 13 extending in the fourth step, based on actual measurement, calculation, and experience. The depth of the groove MZ by the grooving processing is a depth at which the fracture 13 is exposed from the bottom surface of the groove MZ after the fourth step.

According to such a laser processing method, after the fourth step, the fracture 13 extending from the modified region 11 in the wafer 20 reaches the bottom surface of the groove MZ along the line 15. Therefore, an effect similar to the above description in that it is possible to reliably chip the wafer 20 for each functional element 22a by the fracture 13 is exhibited. At this time, the fourth step may be the grinding step. Examples of the other fourth step include a transport step and a cleaning step.

In the above embodiments and the above modification example, the phase that “such that the fracture 13 extending from the modified region 11 reaches the bottom surface of the groove MZ along the line 15” includes, for example, a case where the fracture 13 does not reach the bottom surface of the groove MZ in a part of the line 15 as long as processing is performed for the purpose of chipping the wafer 20 in the subsequent step.

### REFERENCE SIGNS LIST

4 image capturing unit (internal observation camera)
11 modified region
13, 13a, 13b, 13c fracture
15 line
20 wafer
22a functional element
23 street
HM protective film
L laser light
MZ groove (recess)

1: A laser processing method comprising:
a first step of preparing a wafer including a plurality of functional elements disposed to be adjacent to each other via a street;
a second step of, after the first step, forming a modified region in the wafer along a line passing through the street; and
a third step of, after the second step, irradiating the street with laser light such that a surface layer of the street is removed, and a fracture extending from the modified region reaches a bottom surface of a recess formed by removing the surface layer, along the line.

2: The laser processing method according to claim 1, further comprising: a grinding step of grinding and thinning the wafer.

3: The laser processing method according to claim 2, wherein the grinding step is performed after the first step and before the second step.

4: The laser processing method according to claim 2, wherein the grinding step is performed after the second step and before the third step.

5: The laser processing method according to claim 2, wherein the grinding step is performed after the third step.

6: The laser processing method according to claim 1, further comprising:
an information acquisition step of acquiring fracture extension information regarding extension of the fracture, before the third step,
wherein, in the third step, the street is irradiated with the laser light based on the fracture extension information such that the surface layer is removed and the fracture reaches the bottom surface of the recess along the line.

7: The laser processing method according to claim 6, wherein, in the information acquisition step, the fracture extension information is acquired based on an image capturing result obtained by an internal observation camera capturing an image of the wafer after the modified region is formed in the second step.

8: The laser processing method according to claim 6, wherein the fracture extension information includes information regarding whether or not the fracture has reached the street.

9: The laser processing method according to claim 8, wherein, in the third step, only a region not reached by the fracture along the line in the street is irradiated with the laser light along the line based on the fracture extension information such that the surface layer is removed, and the fracture reaches the bottom surface of the recess along the line.

10: The laser processing method according to claim 6, further comprising:
a protective film applying step of applying a protective film onto at least the street of the wafer before the second step.

11: The laser processing method according to claim 1, wherein, in the second step, the modified region is formed in the wafer along the line such that the fracture does not reach the street.

12: A laser processing method comprising:
a first step of preparing a wafer including a plurality of functional elements disposed to be adjacent to each other via a street;
a second step of, after the first step, forming a modified region in the wafer along a line passing through the street;
a third step of, after the second step, irradiating the street with laser light such that a surface layer of the street is removed; and
a fourth step of processing the wafer after the third step,
wherein, in the third step, the street is irradiated with the laser light such that a fracture extending from the modified region reaches a bottom surface of a recess formed by removing the surface layer, along the line after the fourth step.

13: The laser processing method according to claim 12, wherein the fourth step is a grinding step of grinding and thinning the wafer.
